(19) United States
(12) Patent Application Publication
(10) Pub. No.: US 2011/0149670 A1
(43) Pub. Date: Jun. 23, 2011

(54) Spin valve device including graphene, method of manufacturing the same, and magnetic device including the spin valve device

(75) Inventors: Jin-seong Heo, Suwon-si (KR); Sun-ae Seo, Hwaseong-si (KR); Yun-sung Woo, Suwon-si (KR); Hyun-jong Chung, Hwaseong-si (KR)

(73) Assignee: Samsung Electronics Co., Ltd., Suwon-si (KR)

(21) Appl. No.: 12/805,909

(22) Filed: Aug. 24, 2010

(30) Foreign Application Priority Data
Dec. 21, 2009 (KR) 10-2009-0128333

(51) Int. Cl. G11C 11/06; B32B 9/00; B32B 15/04; G11B 5/127

(52) U.S. Cl. 365/225.5; 428/688; 428/457; 216/22

(57) ABSTRACT

Provided are a spin valve device including graphene, a method of manufacturing the spin valve device, and a magnetic device including the spin valve device. The spin valve device may include at least one of a graphene sheet or a hexagonal boron nitride (h-BN) sheet between a lower magnetic layer and an upper magnetic layer. The graphene sheet may have a single layer structure or a multilayer structure. The spin valve device may further include a spacer between the lower magnetic layer and the graphene sheet. The spin valve device may further include a spacer between the graphene sheet and the upper magnetic layer.

### CROSS-REFERENCE TO RELATED APPLICATIONS

This application claims priority under U.S.C. §119 to Korean Patent Application No. 10-2009-0128333, filed on Dec. 21, 2009, in the Korean Intellectual Property Office (KIPO), the entire contents of which are incorporated herein by reference.

### BACKGROUND

1. Field

Example embodiments relate to magnetic devices and methods of manufacturing the same, and more particularly, to spin valve devices including graphene, methods of manufacturing the spin valve devices, and magnetic devices including the spin valve devices.

2. Description of the Related Art

Research has been widely conducted on graphene as an alternative semiconductor. Graphene is an atomically thin 2D plane having metallic properties and in which carbon atoms are packed in a two-dimensional (2D) hexagonal structure. Also, a conduction band and a valence band of graphene overlap with each other at one point. Furthermore, graphene has a relatively long spin relaxation length due to lower intrinsic spin-orbit coupling, which is potentially useful for spintronics applications.

A giant magnetoresistive (GMR) device may include a non-magnetic layer as a spacer between ferromagnetic layers. Magnetoresistance, which is a result of scattering of electrons when the electrons pass through the GMR device, varies according to magnetization directions of the ferromagnetic layers. The GMR device is a device that operates based on such magnetoresistance variations. The efficiency of the GMR device is related to the electrical resistance and magnetic resistance. That is, the efficiency of the GMR device may be improved by maintaining the electrical resistance at a relatively low level and increasing the magnetic resistance.

### SUMMARY

Provided are spin valve devices that may increase a magnetic resistance and maintain an electrical resistance at a relatively low level, methods of manufacturing the spin valve devices and magnetic devices including the spin valve devices. Additional aspects will be set forth in part in the description which follows and, in part, will be apparent from the description, or may be learned by practice of example embodiments.

According to example embodiments, a spin valve device may include a lower magnetic layer, a sheet on the lower magnetic layer, and an upper magnetic layer on the sheet, wherein the sheet includes at least one of graphene and hexagonal boron nitride (h-BN).

The sheet may be a graphene sheet having a single layer structure or a multilayer structure. The spin valve device may further include a spacer between the lower magnetic layer and the graphene sheet. The spin valve device may further include a spacer between the graphene sheet and the upper magnetic layer. Each of the upper magnetic layer and the lower magnetic layer may include at least one of nickel (Ni), cobalt (Co), iron (Fe), and a combination thereof.

According to example embodiments, a magnetic memory device may include a switching device and a storage node connected to the switching device, wherein the storage node may be the spin valve device of example embodiments. According to example embodiments, a spin transfer nano-oscillator may include the spin valve device of example embodiments.

According to example embodiments, a method of manufacturing a spin valve device may include forming a sheet on a lower magnetic layer, forming an upper magnetic layer on the sheet, and forming a plurality of cell patterns by sequentially etching the upper magnetic layer, the sheet, and the lower magnetic layer, wherein the sheet is at least one of graphene and hexagonal boron nitride (h-BN).

The sheet may be a graphene sheet having a single layer structure or a multilayer structure. The method may further include forming a lower spacer between the lower magnetic layer and the graphene sheet. The method may further include forming an upper spacer between the upper magnetic layer and the graphene sheet.

According to example embodiments, a method of manufacturing a spin valve device may include forming a lower magnetic layer pattern on a substrate, forming a sheet on a top surface of the lower magnetic layer pattern, and forming an upper magnetic layer pattern on the sheet, wherein the sheet is at least one of graphene and hexagonal boron nitride (h-BN).

The sheet may be a graphene sheet having a single layer structure or a multilayer structure. The method may further include forming a lower spacer pattern between the lower magnetic layer pattern and the graphene sheet. The method may further include forming an upper spacer pattern between the upper magnetic layer pattern and the graphene sheet.

### BRIEF DESCRIPTION OF THE DRAWINGS

These and/or other aspects will become apparent and more readily appreciated from the following description of example embodiments, taken in conjunction with the accompanying drawings of which:

FIG. 1 is a cross-sectional view of a spin valve device according to example embodiments;

FIG. 2 is a cross-sectional view of a spin valve device according to example embodiments;

FIG. 3 is a cross-sectional view of a magnetic memory device including a spin valve device, according to example embodiments;

FIG. 4 is a cross-sectional view of a magnetic packet memory (MPM) device including a spin valve device, according to example embodiments;

FIGS. 5 through 7 are cross-sectional views illustrating a method of manufacturing the spin valve device of FIG. 1 or 2, according to example embodiments; and

FIGS. 8 through 11 are cross-sectional views illustrating a method of manufacturing the spin valve device of FIG. 1 or 2, according to example embodiments.

### DETAILED DESCRIPTION

Reference will now be made in detail to example embodiments, examples of which are illustrated in the accompanying drawings. In the drawings, thicknesses of layers or regions are exaggerated for clarity. Example embodiments may, however, be embodied in many different forms and should not be construed as being limited to example embodiments set forth herein; rather, these example embodiments are provided so that this disclosure will be thorough and complete, and will fully convey the concept of example embodiments to those of ordinary skill in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

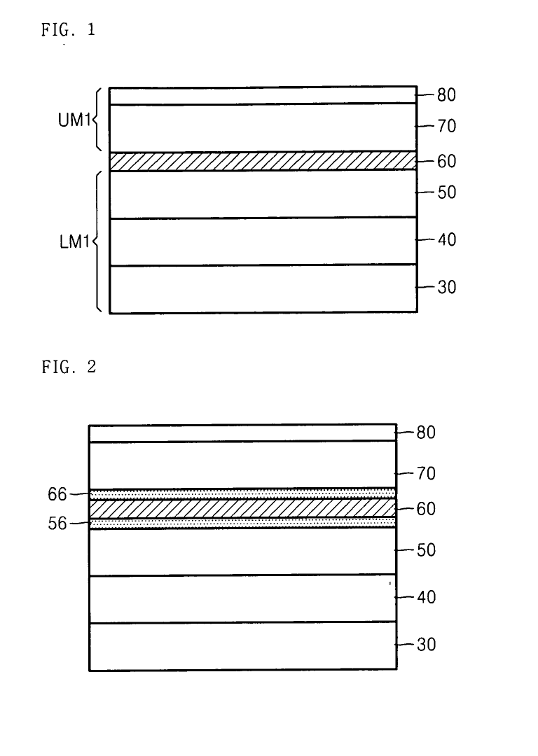

FIG. 1 is a cross-sectional view of a spin valve device according to example embodiments. For example, the spin valve device may be a giant magnetoresistive (GMR) device. Referring to FIG. 1, the spin valve device may include a lower magnetic layer LM1, an intermediate layer 60, and an upper magnetic layer UM 1 which are sequentially stacked. The lower magnetic layer LM1 may include a ferromagnetic layer and a plurality of magnetic layers. For example, the lower magnetic layer LM1 may include a seed layer 30, a pinning layer 40, and a pinned layer 50 which are sequentially stacked, or may further include other material layers. The lower magnetic layer LM1 may include at least one of nickel (Ni), cobalt (Co), iron (Fe), and a compound thereof. For example, the compound may be CoNi or NiFe.

The intermediate layer 60 may be a non-magnetic layer or an insulating layer. The intermediate layer 60 may be a graphene sheet or a hexagonal boron nitride (h-BN) sheet. The graphene sheet may have a single layer structure or a multilayer structure. If the graphene sheet has a multilayer structure, the number of layers may be large enough to allow normal operations of the spin valve device. The upper magnetic layer UM1 may include a ferromagnetic layer. The upper magnetic layer UM1 may include a free layer 70 and a capping layer 80 disposed on the free layer 70. The free layer 70 may be a ferromagnetic layer. A magnetization direction of the pinned layer 50 may be fixed in a given direction whereas a magnetization direction of the free layer 70 varies according to an external magnetic field or spin-polarized current. The upper magnetic layer UM1 may include at least one of Ni, Co, and Fe.

Because a relatively thin graphene sheet or an h-BN sheet is disposed between the pinned layer 50 and the free layer 70, an electrical resistance may be reduced and a magnetoresistance (MR) ratio may be increased.

FIG. 2 is a cross-sectional view of a spin valve device according to example embodiments. The same elements as those in FIG. 1 are denoted by the same reference numerals and a detailed explanation thereof will not be given.

Referring to FIG. 2, a lower spacer 56 may be disposed between the pinned layer 50 and the intermediate layer 60. An upper spacer 66 may be disposed between the free layer 70 and the intermediate layer 60. Alternatively, only one of the lower spacer 56 and the upper spacer 66 may be provided. The lower and upper spacers 56 and 66 may be formed of the same material or different materials. Whether the lower and upper spacers 56 and 66 are formed of the same material may be determined according to whether the pinned layer 50 and the free layer 70 are formed of the same material. However, even though the pinned layer 50 and the free layer 70 are formed of the same material, the lower and upper spacers 56 and 66 may be formed of the same material. For example, the lower spacer 56 may be formed of manganese (Mn) or copper (Cu). For example, the upper spacer 66 may be formed of Mn or Cu.

In FIGS. 1 and 2, the lower magnetic layer LM1 may act as the upper magnetic layer UM1 and the upper magnetic layer UM1 may act as the lower magnetic layer LM1. For example, the lower magnetic layer LM1 may have the configuration of the upper magnetic layer UM1 including a free layer and the upper magnetic layer UM1 may have the configuration of the lower magnetic layer LM1 including a pinned layer.

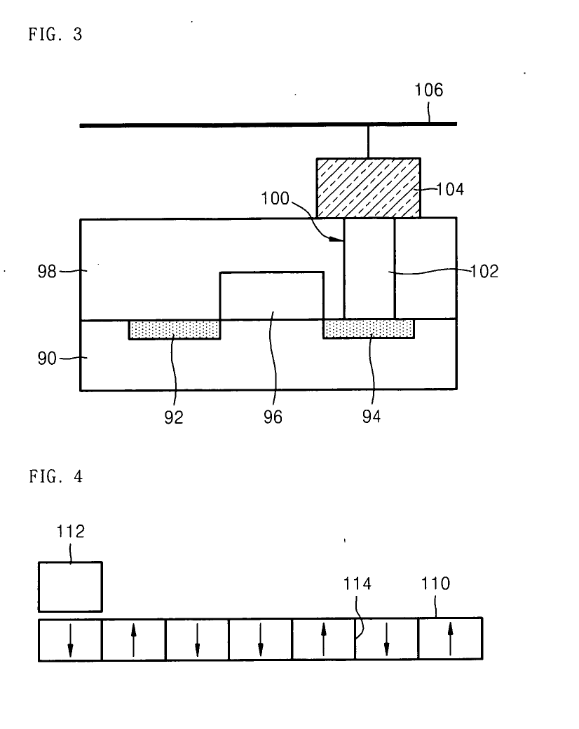

FIG. 3 is a cross-sectional view of a memory device including a spin valve device, according to example embodiments. The memory device may be a magnetic random access memory (MRAM) device.

Referring to FIG. 3, a transistor including first and second impurity regions 92 and 94 and a gate 96 may be disposed on a substrate 90. The substrate 90 may be any substrate on which a semiconductor transistor may be formed, for example, a P-type or N-type silicon substrate. The first and second impurity regions 92 and 94 may be doped with impurities of a type opposite to impurities included in the substrate 90. One of the first and second impurity regions 92 and 94 may be a source and the other may be a drain. The gate 96 may be disposed on the substrate 90 between the first and second impurity regions 92 and 94. Although the gate 96 is illustrated for convenience as a single layer in FIG. 3, the gate 96 may include a gate insulating layer and a gate electrode. An interlayer insulating layer 98 may be disposed on the substrate 90 to cover the transistor. A contact hole 100 through which the second impurity region 94 is exposed may be formed in the interlayer insulating layer 98, and a conductive plug 102 may be filled in the contact hole 100.

A magnetic tunnel junction (MTJ) structure 104 may be disposed on the interlayer insulating layer 98 to cover a top surface of the conductive plug 102. The MTJ structure 104 may be a storage node storing data. The MTJ structure 104 may be any one of the spin valve devices of FIGS. 1 and 2. A conductive member may be further disposed between the conductive plug 102 and the MTJ structure 104. A conductive line 106 may be connected to the MTJ structure 104. The conductive line 106 may be directly connected to a free layer of the MTJ structure 104, or indirectly connected to the free layer of the MTJ structure 104 through a capping layer or an upper electrode formed on the free layer. The conductive line 106 may be a bit line.

The spin valve devices of FIGS. 1 and 2 may be applied to magnetic devices other than the memory device of FIG. 3. For example, the spin valve devices of FIGS. 1 and 2 may be applied to horizontal and vertical magnetic recording heads.

Any of the spin valve devices of FIGS. 1 and 2 may be used as a magnetic head 112, for writing data to or reading data from a recording medium 110 based on a magnetic domain wall motion, of a magnetic packet memory (MPM) device as shown in FIG. 4.

FIG. 4 is a cross-sectional view of an MPM device including a spin valve device, according to example embodiments. In FIG. 4, reference numeral 114 denotes a magnetic domain wall, and a vertical arrow indicates a vertical magnetic polarization of each magnetic domain of the recording medium 110, that is, data recorded in each domain. An MTJ structure of a magnetic logic device that performs a logic operation using MTJ may be replaced with the spin valve device by example embodiments.

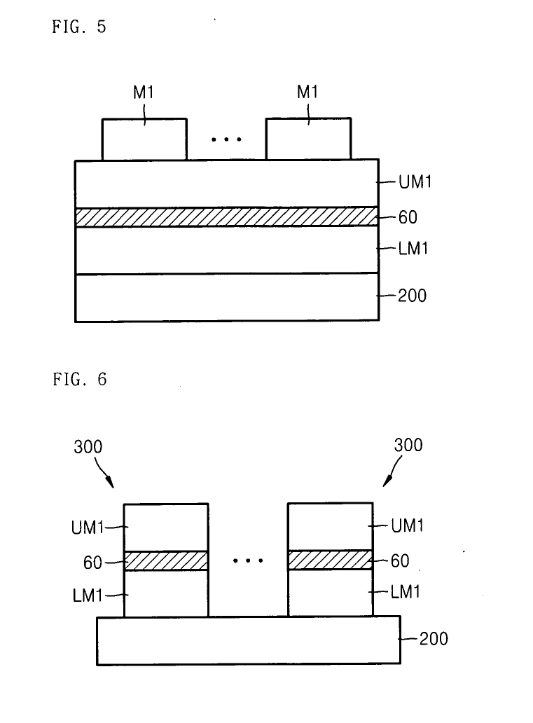

FIGS. 5 through 7 are cross-sectional views illustrating a method of manufacturing the spin valve device of FIG. 1 or 2, according to example embodiments. The same elements as those in FIGS. 1 through 3 are denoted by the same reference numerals and a detailed explanation thereof will be omitted. The same applies to a method of manufacturing the spin valve device of FIG. 1 or 2, according to example embodiments illustrated in FIGS. 8 through 11.

Referring to FIG. 5, the lower magnetic layer LM1 may be formed on the substrate 200. The substrate 200 may be an interlayer insulating layer. The interlayer insulating layer may include a semiconductor device electrically connected to the spin valve device, for example, a switching device, e.g., a transistor or a diode. According to the use of the spin valve device formed on the substrate 200, the substrate 200 may be a conductive substrate, or an insulating substrate with a conductive line formed between the lower magnetic layer LM1 and the substrate 200. A plurality of the spin valve devices may be formed on the substrate 200. The lower magnetic layer LM1 may be patterned in a subsequent process and may be used as lower magnetic layers of the plurality of spin valve devices. Layers and materials of the layers of the lower magnetic layer LM1 have been explained with reference to FIG. 1. After the lower magnetic layer LM1 is formed, the intermediate layer (referred to as the graphene sheet) 60 may be formed on the lower magnetic layer LM1.

The graphene sheet 60 may be formed on an entire top surface of the lower magnetic layer LM1. Other materials for performing a similar function to that of the graphene sheet 60 may be formed instead of the graphene sheet 60. For example, an h-BN sheet may be formed instead of the graphene sheet 60. The graphene sheet 60 may be a single sheet or a plurality of sheets. If the plurality of graphene sheets are formed on the lower magnetic layer LM1, the number of the graphene sheets may be limited to a number that allows normal operations of the spin valve device. The graphene sheet 60 may be formed on the pinned layer 50 of the lower magnetic layer LM1 by epitaxial growth. Alternatively, the graphene sheet 60 may be formed on a layer other than the lower magnetic layer LM1 and may be transferred to the pinned layer 50 of the lower magnetic layer LM1.

After the graphene sheet 60 is formed, the upper magnetic layer UM1 may be formed on the graphene sheet 60. Layers and materials of the layers of the upper magnetic layer UM1 have been explained with reference to FIG. 1. After the upper magnetic layer UM1 is formed, masks M1 defining areas where the spin valve devices are to be formed may be formed on the upper magnetic layer UM1. The masks M1 may be photosensitive patterns. Each of the masks M1 defines an area where each of the spin valve devices in a unit cell is to be formed. After the masks M1 are formed, the upper magnetic layer UM1, the graphene sheet 60, and the lower magnetic layer LM1 around the masks M1 may be sequentially etched. The etching may be performed until the substrate 200 is exposed. After the etching, the masks M1 may be removed. As a result, as shown in FIG. 6, a plurality of patterns, that is, a plurality of spin valve devices 300, may be formed on the substrate 200. The spin valve devices 300 may be GMR devices.

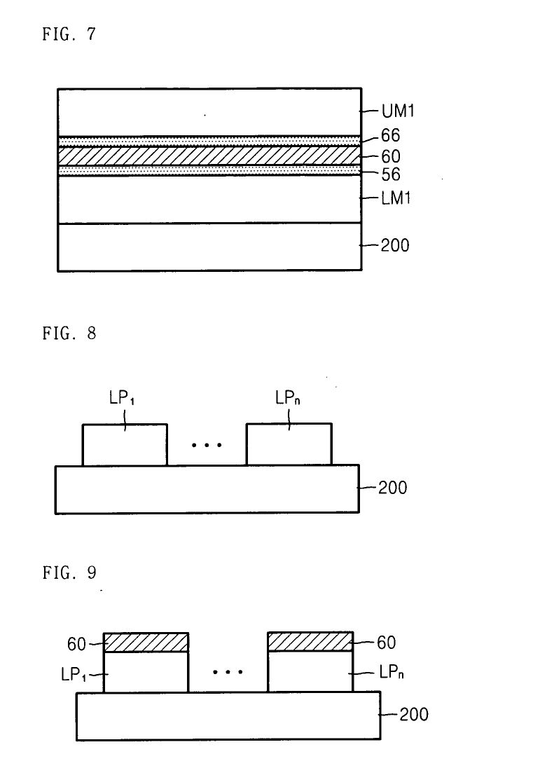

After the lower magnetic layer LM1 is formed as shown in FIG. 5, however, as shown in FIG. 7, the lower spacer 56 may be formed on the lower magnetic layer LM1 and the graphene device 60 may be formed on the lower spacer 56. After the graphene device 60 is formed, the upper spacer 66 may be formed on the graphene device 60 and the upper magnetic layer UM1 may be formed on the upper spacer 66. Materials of the lower and upper spacers 56 and 66 have been explained with reference to FIG. 2.

Once the lower and upper spacers 56 and 66 are provided, because undesired hybridization with carbons in graphene is prevented or reduced and properties of the graphene as a non-ferromagnetic metal are sufficiently strong, an MR ratio may be increased.

FIGS. 8 through 11 are cross-sectional views illustrating a method of manufacturing the spin valve device of FIG. 1 or 2, according to example embodiments. The method of FIGS. 8 through 11 is characterized in that the lower magnetic layer LM1 is patterned in units of cells.

Referring to FIG. 8, a plurality of lower magnetic layer patterns LP₁ . . . LPₙ may be formed on the substrate 200. Each of the lower magnetic layer patterns LP₁ . . . LPₙ may be used as the lower magnetic layer LM1 of each spin valve device in a unit cell. The lower magnetic layer patterns LP₁ . . . LPₙ may be formed by forming the lower magnetic layer LM1 on an entire top surface of the substrate 200, forming masks defining areas where a plurality of the spin valve devices are to be formed in units of cells, etching the lower magnetic layer LM1 by using the masks, and removing the masks. An interlayer insulating layer (not shown) may be filled between the lower magnetic layer patterns LP₁ . . . LPₙ. Because only top surfaces of the lower magnetic layer patterns LP₁ . . . LPₙ are exposed if the interlayer insulating layer is filled between the lower magnetic layer patterns LP₁ . . . LPₙ, graphene may be selectively formed only on the top surfaces of the lower magnetic layer patterns LP₁ . . . LPₙ in a subsequent process of forming a graphene sheet.

Referring to FIG. 9, the graphene sheet 60 may be formed on the lower magnetic layer patterns LP₁ . . . LPₙ. The graphene sheet 60 may be formed to cover the entire top surfaces of the lower magnetic layer patterns LP₁ . . . LPₙ. An h-BN sheet may be formed instead of the graphene sheet 60.

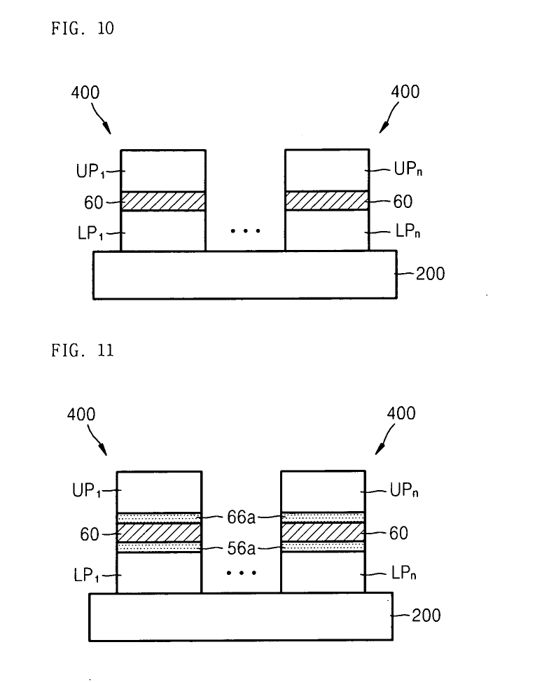

Referring to FIG. 10, upper magnetic layer patterns UP₁ . . . UPₙ may be formed on the graphene sheet 60. The upper magnetic layer patterns UP₁ . . . UPₙ correspond to the lower magnetic layer patterns LP₁ . . . LPₙ in a one-to-one manner. That is, one upper magnetic layer pattern, for example, UP_{I}, may be formed on one lower magnetic layer pattern, for example, LP₁, with the graphene sheet 60 therebetween. In example embodiments, a plurality of spin valve devices 400 may be formed on the substrate 200. The spin valve devices 400 may have the same configuration as that of the spin valve devices 300 of FIG. 6.

Referring to FIG. 11, after lower spacer patterns 56A are formed on the lower magnetic layer patterns LP₁ . . . LPₙ, the graphene sheet 60 may be formed on the lower spacer patterns 56A. After upper spacer patterns 66A are formed on the graphene sheet 60, the upper magnetic layer patterns UP₁ . . . UPₙ may be formed on the upper spacer patterns 66A.

It should be understood that example embodiments described therein should be considered in a descriptive sense only and not for purposes of limitation. Therefore, the scope of example embodiments is defined not by the detailed description but by the appended claims,

What is claimed is:

1. A spin valve device comprising:
a lower magnetic layer;
a sheet on the lower magnetic layer, the sheet including at least one of graphene and hexagonal boron nitride (h-BN); and
an upper magnetic layer on the graphene sheet.

2. The spin valve device of claim 1, wherein the sheet is a graphene sheet.

3. The spin valve device of claim 2, wherein the graphene sheet has a single layer structure or a multilayer structure.

4. The spin valve device of claim 2, further comprising:
a spacer between the lower magnetic layer and the graphene sheet.

5. The spin valve device of claim 4, further comprising:
a spacer between the graphene sheet and the upper magnetic layer.

6. The spin valve device of claim 2, further comprising:
a spacer between the graphene sheet and the upper magnetic layer.

7. The spin valve device of claim 1, wherein each of the upper magnetic layer and the lower magnetic layer includes at least one of nickel (Ni), cobalt (Co), iron (Fe), and a combination thereof.

8. A magnetic memory device comprising:
a storage node connected to a switching device,
wherein the storage node is the spin valve device of claim 1.

9. A spin transfer nano-oscillator comprising the spin valve device of claim 1.

10. A method of manufacturing a spin valve device, the method comprising:
forming a sheet on a lower magnetic layer;
forming an upper magnetic layer on the sheet; and
forming a plurality of cell patterns by sequentially etching the upper magnetic layer, the sheet, and the lower magnetic layer,
wherein the sheet includes at least one of graphene and hexagonal boron nitride (h-BN).

11. The method of claim 10, wherein the sheet is a graphene sheet.

12. The method of claim 11, wherein the graphene sheet has a single layer structure or a multilayer structure.

13. The method of claim 11, further comprising:
forming a lower spacer between the lower magnetic layer and the graphene sheet.

14. The method of claim 13, further comprising:
forming an upper spacer between the upper magnetic layer and the graphene sheet.

15. The method of claim 11, further comprising:
forming an upper spacer between the upper magnetic layer and the graphene sheet.

16. A method of manufacturing a spin valve device, the method comprising:
forming a lower magnetic layer pattern on a substrate;
forming a sheet on a top surface of the lower magnetic layer pattern; and
forming an upper magnetic layer pattern on the sheet,
wherein the sheet includes at least one of graphene and hexagonal boron nitride (h-BN).

17. The method of claim 16, wherein the sheet is a graphene sheet.

18. The method of claim 17, wherein the graphene sheet has a single layer structure or a multilayer structure.

19. The method of claim 17, further comprising:
forming a lower spacer pattern between the lower magnetic layer pattern and the graphene sheet.

20. The method of claim 19, further comprising:
forming an upper spacer pattern between the upper magnetic layer pattern and the graphene sheet.

21. The method of claim 17, further comprising:
forming an upper spacer pattern between the upper magnetic layer pattern and the graphene sheet.
